(19) United States
(12) Patent Application Publication
(10) Pub. No.: US 2023/0421131 A1
(43) Pub. Date: Dec. 28, 2023

(54) METHOD FOR MANUFACTURING RESONANCE DEVICE, AND RESONANCE DEVICE

(71) Applicant: Murata Manufacturing Co., Ltd., Nagaokakyo-shi (JP)

(72) Inventors: Masakazu FUKUMITSU, Nagaokakyo-shi (JP); Naoto YATANI, Nagaokakyo-shi (JP); Ryota KAWAI, Nagaokakyo-shi (JP); Fumiya ENDOU, Nagaokakyo-shi (JP)

(21) Appl. No.: 18/462,838

(22) Filed: Sep. 7, 2023

Related U.S. Application Data
(63) Continuation of application No. PCT/JP2021/039315, filed on Oct. 25, 2021.

(30) Foreign Application Priority Data
Mar. 31, 2021 (JP) 2021-059090

(51) Int. Cl. H03H 9/17; H03H 9/05; H03H 9/09; H03H 3/02

(52) U.S. Cl. CPC H03H 9/171; H03H 9/0538; H03H 9/09; H03H 3/02

(57) ABSTRACT

A method is provided for manufacturing a resonance device, the method includes forming a recessed portion that forms a vibration space for a resonator in an object that is at least one of an upper lid and a lower lid and includes etching on the object by isotropic etching while the object is covered with a mask having a peripheral portion having a frame shape and a stopper formation that extends from the peripheral portion toward an inside of the peripheral portion. The method further includes etching the object while the object is covered with the mask to form a stopper at a position overlapping with the stopper formation on a bottom surface of the recessed portion in a plan view of the object. In this aspect, the stopper restricts collision of the resonator with the bottom surface of the recessed portion.

### CROSS REFERENCE TO RELATED APPLICATIONS

This application is a continuation of International Application No. PCT/JP2021/039315, filed Oct. 25, 2021, which claims priority to Japanese Patent Application No. 2021-059090, filed Mar. 31, 2021, the entire contents of each of which are hereby incorporated by reference in their entirety.

### TECHNICAL FIELD

The present invention relates to a method for manufacturing a resonance device and to a resonance device.

### BACKGROUND

Currently, a resonance device is provided as a device for achieving a time measurement function in an electronic device in which a resonator of the resonance device, such as a piezoelectric vibrator, is interposed between an upper lid and a lower lid. Moreover, a recessed portion formed in each of the upper lid and the lower lid forms a vibration space for the resonator in such existing designs.

For example, International Publication No. 2019-207829 (hereinafter “Patent Document 1”), discloses a resonance device in which a recessed portion in each of an upper lid and a lower lid is formed by etching.

However, in the existing art, when an impact is applied to the upper lid from above, the resonator is largely bent and displaced until it collides with the bottom portion of the recessed portion of the lower lid, and thus the resonator may be damaged.

### SUMMARY OF THE INVENTION

Accordingly, it is an object of the present invention to provide a method for manufacturing a resonance device and a resonance device that suppress damages to a resonator.

In an exemplary aspect, a method is provided for manufacturing a resonance device having a resonator and an upper lid and a lower lid that face each other with the resonator interposed between the upper lid and the lower lid. The method includes forming a recessed portion that forms a vibration space for the resonator in an object that is at least one of the upper lid and the lower lid. The forming of the recessed portion includes etching the object by isotropic etching while the object is covered with a mask having a peripheral portion having a frame shape and a stopper formation portion that extends from the peripheral portion toward an inside of the peripheral portion. The method further includes etching the object by anisotropic etching while the object is covered with the mask to form a stopper at a position overlapping with the stopper formation portion on a bottom surface of the recessed portion in a plan view of the object. In this aspect, the stopper is configured to restrict collision of the resonator with the bottom surface of the recessed portion.

In another exemplary aspect, a is provided method for manufacturing a resonance device having a resonator and an upper lid and a lower lid provided to face each other with the resonator interposed between the upper lid and the lower lid. The method includes forming a recessed portion that forms a vibration space for the resonator in an object that is at least one of the upper lid and the lower lid. The forming of the recessed portion in the object includes etching the object by isotropic etching while the object is covered with a mask having a pillar formation portion, and etching the object by anisotropic etching while the object is covered with the mask to form a pillar portion at a position overlapping with the pillar formation portion on a bottom surface of the recessed portion in a plan view of the object. In this aspect, the pillar portion has a taper portion that gradually increases in width toward the bottom surface of the recessed portion and is configured to restrict collision of the resonator with the bottom surface of the recessed portion.

In another exemplary aspect, a resonance device is provided that includes a resonator, and an upper lid and a lower lid provided to face each other with the resonator interposed between the upper lid and the lower lid. At least one of the upper lid and the lower lid has a recessed portion that forms a vibration space for the resonator. A bottom surface of the recessed portion is provided with a stopper that extends from an inner side surface of the recessed portion and is configured to restrict collision of the resonator with the bottom surface of the recessed portion.

In yet another exemplary aspect, a resonance device is provided that includes a resonator, and an upper lid and a lower lid provided to face each other with the resonator interposed between the upper lid and the lower lid. At least one of the upper lid and the lower lid has a recessed portion that forms a vibration space for the resonator. A bottom surface of the recessed portion is provided with a pillar portion having a taper portion that gradually increases in width toward the bottom surface of the recessed portion and is configured to restrict collision of the resonator with the bottom surface of the recessed portion.

According to the exemplary aspects of the present invention, damage to a resonator is suppressed and/or minimized.

### BRIEF DESCRIPTION OF DRAWINGS

FIG. 1 is a perspective view schematically illustrating an external appearance of a resonance device according to a first exemplary embodiment.

FIG. 2 is an exploded perspective view schematically illustrating a structure of the resonance device according to the first exemplary embodiment.

FIG. 3 is a plan view of a resonator according to the first exemplary embodiment.

FIG. 4 is a sectional view taken along line A-A′ of FIG. 1.

FIG. 5 is a sectional view taken along line B-B′ of FIG. 1.

FIG. 6A illustrates processing by the resonance device according to the first exemplary embodiment.

FIG. 6B illustrates processing by the resonance device according to the first exemplary embodiment.

FIG. 7A illustrates processing by the resonance device according to the first exemplary embodiment.

FIG. 7B illustrates processing by the resonance device according to the first exemplary embodiment.

FIG. 8A illustrates processing by the resonance device according to the first exemplary embodiment.

FIG. 8B illustrates processing by the resonance device according to the first exemplary embodiment.

FIG. 9A illustrates processing by the resonance device according to the first exemplary embodiment.

FIG. 9B illustrates processing by the resonance device according to the first exemplary embodiment.

FIG. 10A illustrates the operation of the resonance device according to the first exemplary embodiment.

FIG. 10B illustrates the operation of the resonance device according to the first exemplary embodiment.

FIG. 11A illustrates processing by a resonance device according to a second exemplary embodiment.

FIG. 11B illustrates processing by the resonance device according to the second exemplary embodiment.

FIG. 12A illustrates processing by the resonance device according to the second exemplary embodiment.

FIG. 12B illustrates processing by the resonance device according to the second exemplary embodiment.

FIG. 13A illustrates processing by the resonance device according to the second exemplary embodiment.

FIG. 13B illustrates processing by the resonance device according to the second exemplary embodiment.

FIG. 14A illustrates processing by the resonance device according to the second exemplary embodiment.

FIG. 14B illustrates processing by the resonance device according to the second exemplary embodiment.

FIG. 15 illustrates processing by a resonance device according to a third exemplary embodiment.

FIG. 16 illustrates processing by the resonance device according to the third exemplary embodiment.

FIG. 17 illustrates processing by the resonance device according to the third exemplary embodiment.

FIG. 18 illustrates processing by the resonance device according to the third exemplary embodiment.

FIG. 19 illustrates the operation of the resonance device according to the third exemplary embodiment.

### DETAILED DESCRIPTION OF EMBODIMENTS

### First Exemplary Embodiment

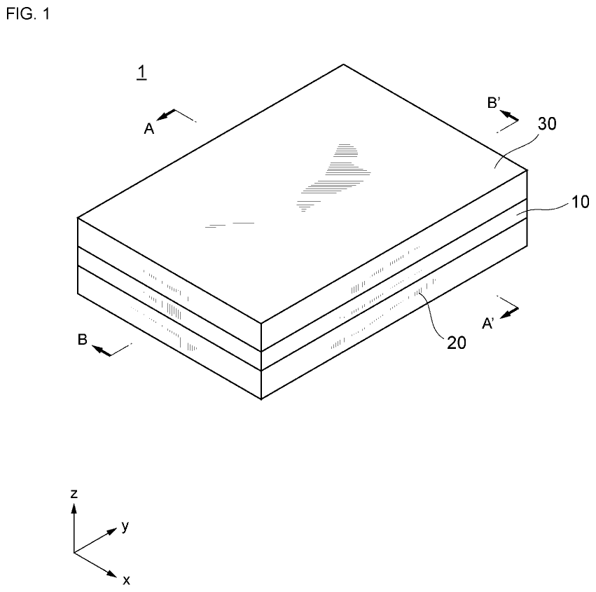

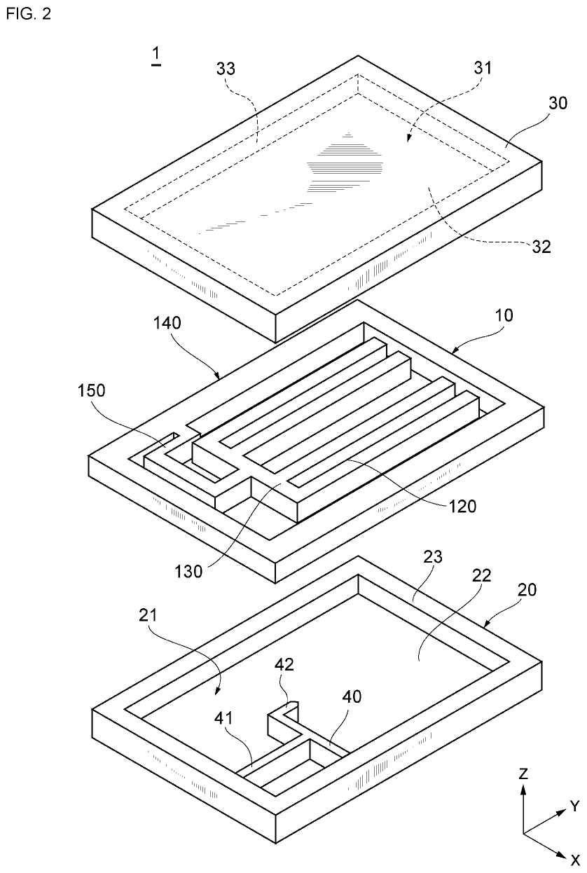

Hereinafter, a first exemplary embodiment will be described with reference to the accompanying drawings. FIG. 1 is a perspective view schematically illustrating an external appearance of a resonance device 1 according to the first exemplary embodiment. In addition, FIG. 2 is an exploded perspective view schematically illustrating a structure of the resonance device 1 according to the first exemplary embodiment.

As shown, the resonance device 1 includes a resonator 10, an upper lid 30, and a lower lid 20. The upper lid 30 and the lower lid 20 are provided so as to face each other with the resonator 10 interposed therebetween. That is, the resonance device 1 is formed by stacking the lower lid 20, the resonator 10, and the upper lid 30 in this order.

When the resonator 10 and the lower lid 20 are joined, and the resonator 10 and the upper lid 30 are joined, the resonator 10 is sealed. Each of the resonator 10, the lower lid 20, and the upper lid 30 is formed using a silicon (Si) substrate. In the resonator 10, the lower lid 20, and the upper lid 30, the Si substrates are joined to each other. In another exemplary aspect, the resonator 10 and the lower lid 20 may be formed using a silicon on insulator (SOI) substrate.

The resonator 10 is a micro electro mechanical systems (MEMS) resonator manufactured using MEMS technologies. Note that in the present embodiment, the resonator 10 formed using a silicon substrate will be described as an example. Hereinafter, each constituent of the resonance device 1 will be described in detail.

Upper Lid 30

The upper lid 30 includes a bottom plate 32 and a side wall 33. The bottom plate 32 has a rectangular plate shape and is provided along an XY plane. The side wall 33 extends in a Z-axis direction (that is, a stacking direction of the upper lid 30 and the resonator 10) from a peripheral portion of the bottom plate 32. The upper lid 30 is provided with a recessed portion 31 formed by a surface of the bottom plate 32 and an inner surface of the side wall 33. The recessed portion 31 is provided on a surface of the upper lid 30 facing the resonator 10 and forms a part of a vibration space for the resonator 10.

Lower Lid 20

The lower lid 20 includes a bottom plate 22 and a side wall 23. The bottom plate 22 has a rectangular plate shape and is provided along the XY plane. The side wall 23 extends in the Z-axis direction (that is, a stacking direction of the lower lid 20 and the resonator 10) from a peripheral portion of the bottom plate 22. The lower lid 20 is provided with a recessed portion 21 formed by a surface of the bottom plate 22 and an inner surface of the side wall 23. The recessed portion 21 is provided on a surface of the lower lid 20 facing the resonator 10 and forms a part of the vibration space for the resonator 10. The vibration space for the resonator 10 is sealed in an air-tight manner by the above-described upper lid 30 and the lower lid 20 so as to maintain a vacuum state. The vibration space for the resonator 10 may be filled with a gas such as an inert gas, for example.

According to the exemplary aspect, the bottom plate 22 of the lower lid 20 is provided with a stopper portion 40 (also referred to as a “stopper”) that is configured to restrict collision of the resonator 10 with the bottom plate 22 of the lower lid 20. The stopper portion 40 projects from the bottom plate 22 of the lower lid 20 and linearly extends from an inner side surface of the side wall 23 of the lower lid 20 so as to extend in the X-axis direction. The bottom plate 22 of the lower lid 20 is provided with a connection portion 41 that connects the stopper portion 40 to the side wall 23 of the lower lid 20. The connection portion 41 projects from the bottom plate 22 of the lower lid 20 and linearly extends between a middle position in the longitudinal direction of the stopper portion 40 and the side wall 23 of the lower lid 20 so as to extend in the Y-axis direction. In a plan view of the lower lid 20, the stopper portion 40 is disposed so as to cross base end portions of a plurality of vibration arms 135 described later in the X-axis direction. As further shown, the bottom plate 22 of the lower lid 20 is provided with a pillar portion 42 (also referred to as a “pillar”) connected to the stopper portion 40. The pillar portion 42 projects from the bottom plate 22 of the lower lid 20 and has a larger area than the stopper portion 40 in the plan view of the lower lid 20. For example, in the plan view of the lower lid 20, a dimension of the pillar portion 42 in a direction intersecting with the longitudinal direction of the stopper portion 40 is larger than a dimension of the stopper portion 40 in the same direction.

Resonator 10

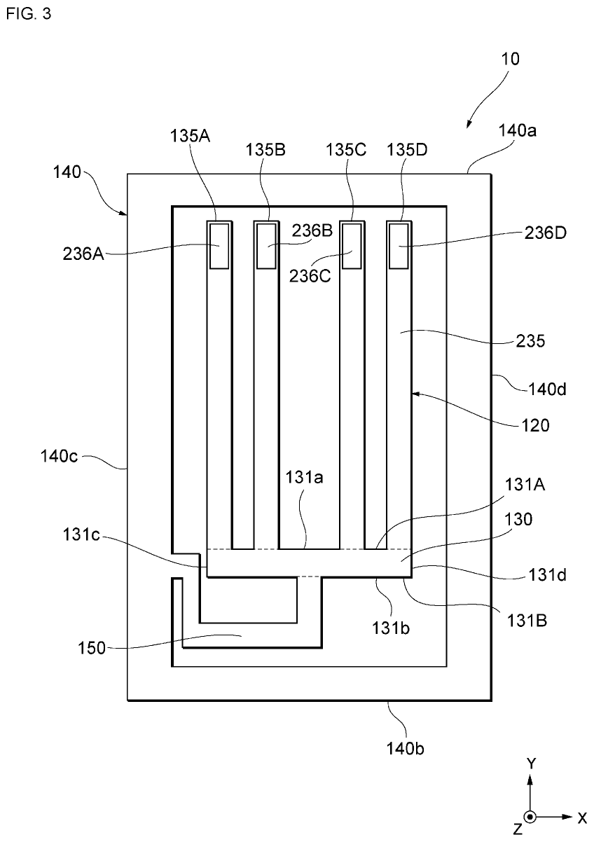

FIG. 3 is a plan view schematically illustrating a structure of the resonator 10 according to the exemplary embodiment.

As illustrate in FIG. 3, the resonator 10 includes a vibration portion 120, a holding portion 140 (also referred to as a “frame”), and a holding arm 150.

Vibration Portion 120

The vibration portion 120 has a rectangular contour expanding along the XY plane in the orthogonal coordinate system illustrated in FIG. 3. The vibration portion 120 is provided on an inner side of the holding portion 140, and a space is formed between the vibration portion 120 and the holding portion 140. In the example illustrated in FIG. 3, the vibration portion 120 is a tuning fork type vibrator and has a base portion 130 (also referred to as a “base”) and four vibration arms 135A, 135B, 135C, and 135D (also collectively referred to as “vibration arm 135”). It is noted that the number of vibration arms is not limited to four and can be, for example, set to an appropriate number equal to or more than three vibration arms. In the present embodiment, the respective vibration arms 135 and the base portion 130 are integrally formed.

In a plan view, the base portion 130 has long sides 131a and 131b in the X-axis direction and short sides 131c and 131d in the Y-axis direction. The long side 131a is one side of a front end surface 131A (hereinafter, also referred to as “front end 131A”) of the base portion 130, and the long side 131b is one side of a rear end surface 131B (hereinafter, also referred to as “rear end 131B”) of the base portion 130. In the base portion 130, the front end 131A and the rear and 131B face each other. The front end 131A of the base portion 130 is connected to the vibration arms 135, and the rear end 131B of the base portion 130 is connected to the holding arm 150.

The vibration arms 135 extend in the Y-axis direction and have the same size. The vibration arms 135 are provided parallel to the Y-axis direction between the base portion 130 and the holding portion 140. One end of each vibration arm 135 is a fixed end connected to the front end 131A of the base portion 130, and the other end is an open end. In addition, the vibration arms 135 are arranged in parallel at a predetermined interval in the X-axis direction. It is noted that, for example, the width of each vibration arm 135 in the X-axis direction is approximately 50 μm, and the length in the Y-axis direction is approximately 465 μm.

A surface (e.g., the surface facing the upper lid 30) of the vibration portion 120 is provided with a protective film 235 in an exemplary aspect. Moreover, a part of a surface of the protective film 235 in each vibration arm 135 can be provided with a frequency adjustment film 236. The protective film 235 and the frequency adjustment film 236 are used for adjustment of a resonance frequency of the vibration portion 120. It is noted that the protective film 235 does not have to cover the entire surface of the vibration portion 120, but preferably covers the entire surface of the vibration portion 120 so as to protect an electrode film and a piezoelectric thin film of a base against damage during frequency adjustment.

Moreover, the frequency adjustment film 236 is provided on the upper surface of the protective film 235. A surface of the frequency adjustment film 236 is exposed in a region where displacement due to vibration in the vibration portion 120 is relatively large. For example, the surface of the frequency adjustment film 236 is exposed at a leading end of each vibration arm 135.

Holding Portion 140

The holding portion 140 (also referred to as a frame) is formed into a rectangular frame shape along the XY plane. In a plan view, the holding portion 140 is provided so as to surround an outer side portion of the vibration portion 120 along the XY plane. In alternative aspects, the holding portion 140 may be provided in at least a part of the periphery of the vibration portion 120 and is not limited to having a frame shape. For example, the holding portion 140 may be provided in the periphery of the vibration portion 120 to such an extent that the holding portion 140 can hold the vibration portion 120 and be joined to the upper lid 30 and the lower lid 20.

In the holding portion 140, frame bodies 140a to 140d each having a prism shape are integrally formed. The frame body 140a faces the open ends of the vibration arms 135, and the longitudinal direction of the frame body 140a coincides with the X-axis direction. The frame body 140b faces the rear end 131B of the base portion 130, and the longitudinal direction of the frame body 140b coincides with the X-axis direction. The frame body 140c faces a side end (short side 131c) of the base portion 130 and the vibration arm 135A, and the longitudinal direction of the frame body 140c coincides with the Y-axis direction. One end of the frame body 140c is connected to the frame body 140a, and another end is connected to the frame body 140b. The frame body 140d faces a side end (the short side 131d) of the base portion 130 and the vibration arm 135D, and the longitudinal direction of the frame body 140d coincides with the Y-axis direction. One end of the frame body 140d is connected to the frame body 140a, and another end is connected to the frame body 140b.

Holding Arm 150

The holding arm 150 is provided on an inner side of the holding portion 140 and connects the rear end 131B of the base portion 130 to the frame body 140c. The holding arm 150 extends, from a central position in the X-axis direction of the rear end 131B of the base portion 130, in a direction (a −Y direction) toward the frame body 140b. In addition, the holding arm 150 is bent in a direction (a −X direction) toward the frame body 140c and extends in the same direction. Moreover, the holding arm 150 is bent in a direction (a +Y direction) toward the frame body 140a and extends in the same direction. Furthermore, the holding arm 150 is bent in a direction (the −X direction) toward the frame body 140c and connected to the frame body 140c.

Multilayer Structure

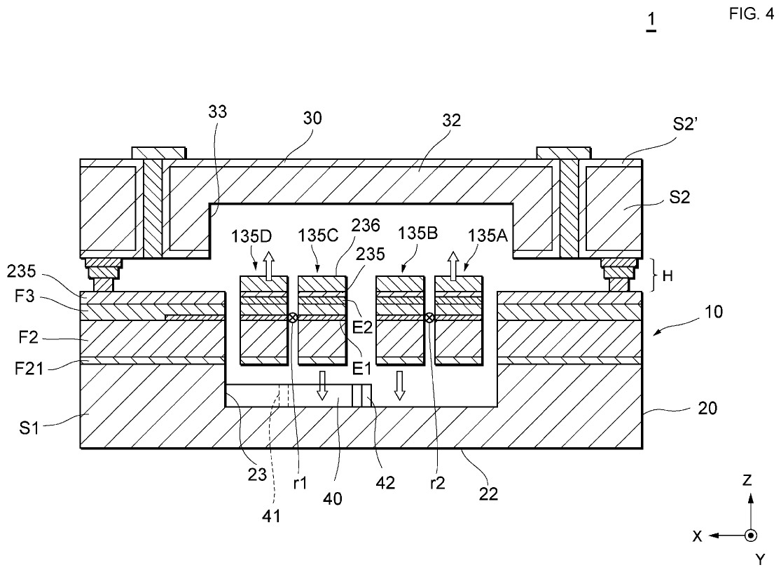

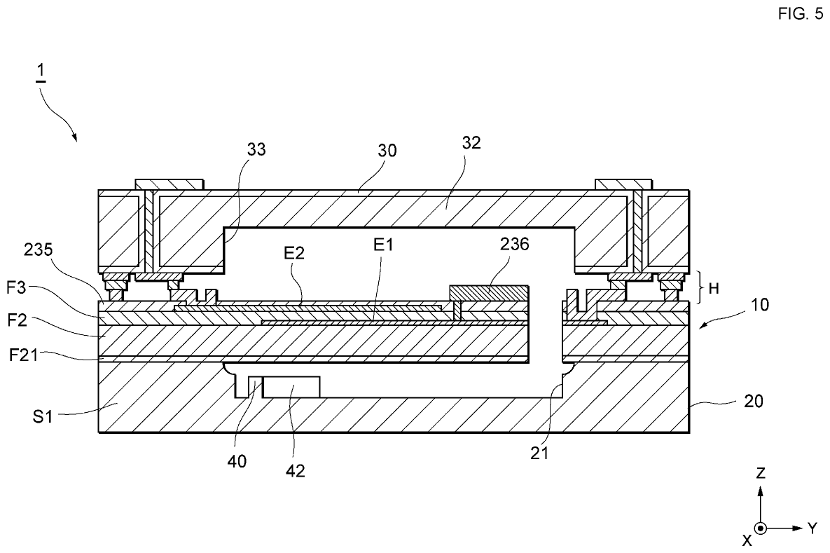

Next, a multilayer structure of the resonance device 1 will be described. FIG. 4 is a schematic view schematically illustrating a section cut along line A-A′ of FIG. 1. FIG. 5 is a schematic view schematically illustrating a section cut along line B-B′ of FIG. 1.

The bottom plate 22 and the side wall 23 of the lower lid 20 is integrally formed by a silicon (Si) wafer S1. In addition, the lower lid 20 is joined to the holding portion 140 of the resonator 10 by an upper surface of the side wall 23. According to an exemplary aspect, the Si wafer S1 is formed from non-degenerate silicon.

As shown, the stopper portion 40 extends along the X-axis direction from the side wall 23 of the lower lid 20. The stopper portion 40 extends, for example, to the central position in the X-axis direction in the recessed portion 21 of the lower lid 20 and crosses the vibration arm 135C and the vibration arm 135D in the X-axis direction.

The upper lid 30 is formed of a silicon (Si) wafer S2 having a predetermined thickness. The side wall 33 of the upper lid 30 is joined to the holding portion 140 of the resonator 10. A front surface and a back surface of the upper lid 30 facing the resonator 10 are preferably covered with a silicon oxide layer S2′. Moreover, a joint portion H is formed between the side wall 33 of the upper lid 30 and the holding portion 140. The joint portion H is formed of, for example, a metal film such as an aluminum (Al) film and a germanium (Ge) film. The joint portion H may be formed of a metal film such as a gold (Au) film and a tin (Sn) film.

In the resonance device 1, the holding portion 140, the base portion 130, the vibration arms 135, and the holding arm 150 are integrally formed by the same process. In the resonance device 1, a silicon (Si) substrate F2, a metal layer E1, a piezoelectric thin film F3, a metal layer E2, the protective film 235, and the frequency adjustment film 236 are stacked in this order.

According to the exemplary aspect, the Si substrate F2 is formed of, for example, a degenerate n-type Si semiconductor having a thickness of approximately 6 μm. The Si substrate F2 may contain phosphorus (P), arsenic (As), or antimony (Sb), or the like as an n-type dopant. The resistance value of the n-type degenerate semiconductor to be used for the Si substrate F2 is, for example, less than 1.6 mΩ·cm, and more preferably equal to or less than 1.2 mΩ·cm. A lower surface of the Si substrate F2 is provided with a silicon oxide layer F21. As a result, the temperature characteristics of the Si substrate F2 is improved.

According to an exemplary aspect, the metal layers E1 and E2 are formed using, for example, Mo (molybdenum), aluminum (Al), or the like having a thickness of approximately 0.1 to 0.2 μm.

Moreover, the metal layer E1 can be configured to function as a lower electrode of the vibration portion 120. In addition, the metal layer E1 also can be configured to function as a wire for connecting the lower electrode to an alternate current power supply provided outside the resonator 10.

The metal layer E2 is configured to function as an upper electrode of the vibration portion 120. In addition, the metal layer E2 also is configured to function as a wire for connecting the upper electrode to a circuit provided outside the resonator 10.

The piezoelectric thin film F3 converts an applied voltage to vibration and contains, for example, an oxide or a nitride such as aluminum nitride (AlN) as a principal component. The piezoelectric thin film F3 is formed of, for example, scandium aluminum nitride (ScAlN). ScAlN is obtained by substituting a part of aluminum in aluminum nitride with scandium. The piezoelectric thin film F3 has, for example, a thickness of 1 μm, and may have a thickness of approximately 0.2 μm to 2 μm.

In operation and upon excitation, the piezoelectric thin film F3 expands and contracts in an in-plane direction of the XY plane in accordance with an electric field applied to the piezoelectric thin film F3 by the metal layers E1 and E2. Due to the expansion and the contraction of the piezoelectric thin film F3, the vibration arms 135 displace the open ends thereof toward the inner surfaces of the lower lid 20 and the upper lid 30 to vibrate in an out-of-plane bending vibration mode.

The protective film 235 is an insulator layer that protects the metal layer E2 and is formed of, for example, a nitride film such as AlN and silicon nitride (SiN) or an oxide film such as tantalum pentoxide (Ta₂O₅) and SiO₂. The protective film 235 is provided so as to cover a surface in the metal layer E2 of the vibration portion 120 facing the upper lid 30.

The frequency adjustment film 236 is a film for adjusting a resonance frequency of the vibration portion 120 and is formed from, for example, a metal such as molybdenum, tungsten, gold, platinum, nickel, aluminum, titanium, or the like. The frequency adjustment film 236 is provided in a region where displacement due to vibration in the vibration portion 120 is relatively large. The frequency adjustment film 236 is, for example, provided so as to cover the protective film 235 at the leading end of each vibration arm 135.

Next, processing for forming the stopper portion 40 on the lower lid 20 of the resonance device 1 according to the first exemplary embodiment will be described. It is noted that similar processing is performed when a stopper portion is formed on the upper lid 30 of the resonance device 1.

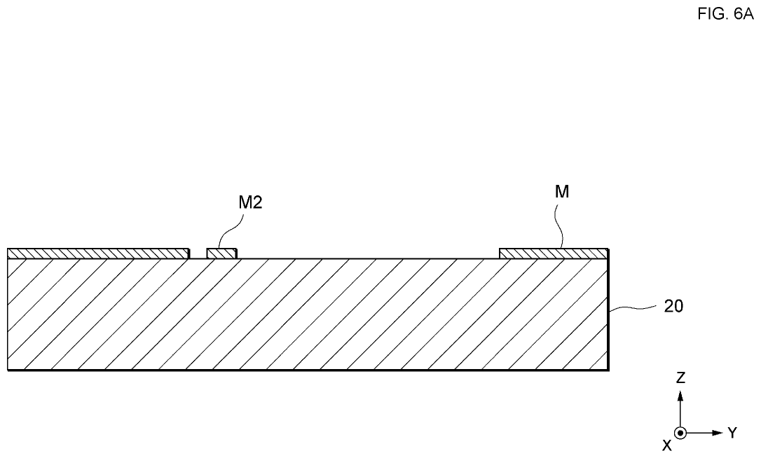

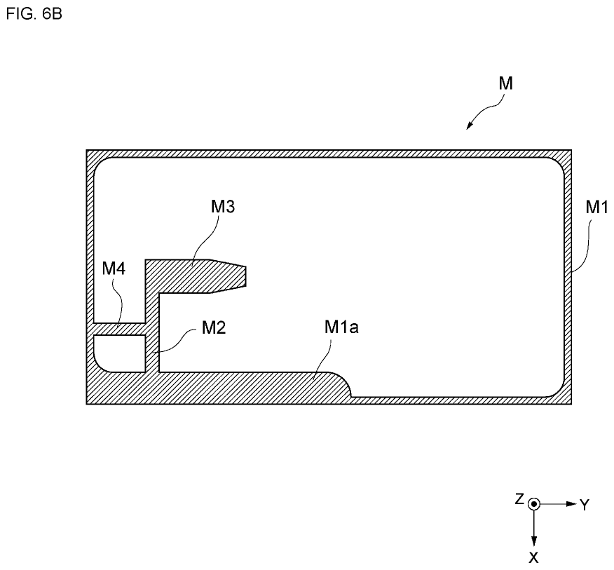

First, as illustrated in FIG. 6A, by applying a resist to the lower lid 20, the upper surface of the lower lid 20 is covered with a mask M. FIG. 6B illustrates a shape of the mask M in a plan view in a step illustrated in FIG. 6A. As illustrated in FIG. 6B, the mask M has a peripheral portion M1 having a frame shape, a stopper formation portion M2 extending from the peripheral portion M1 toward the inside of the peripheral portion M1, a pillar formation portion M3 connected to the stopper formation portion M2 and having a larger area than the stopper formation portion M2 in a plan view of the lower lid 20, and a connection formation portion M4 connecting the stopper formation portion M2 to a short side of the peripheral portion M1 of the mask M. The peripheral portion M1 has a rectangular annular shape, and an extension portion M1a is formed in a part of an inner edge of the peripheral portion M1. The extension portion M1a extends from one corner portion of the peripheral portion M1 to a substantially central position of a long side. The stopper formation portion M2 linearly extends from an inner edge of the extension portion M1a to a substantially central position of a short side of the peripheral portion M1. The leading end of the stopper formation portion M2 is provided with the pillar formation portion M3. The pillar formation portion M3 has a larger area than the stopper formation portion M2 in a plan view of the lower lid 20 and extends from the leading end of the stopper formation portion M2 in a direction along a long side of the peripheral portion M1 so as to be farther away from the peripheral portion M1. In the plan view of the lower lid 20, the dimension of the pillar formation portion M3 in a width direction intersecting with the longitudinal direction of the stopper formation portion M2 is larger than the dimension of the stopper formation portion M2 in the same direction.

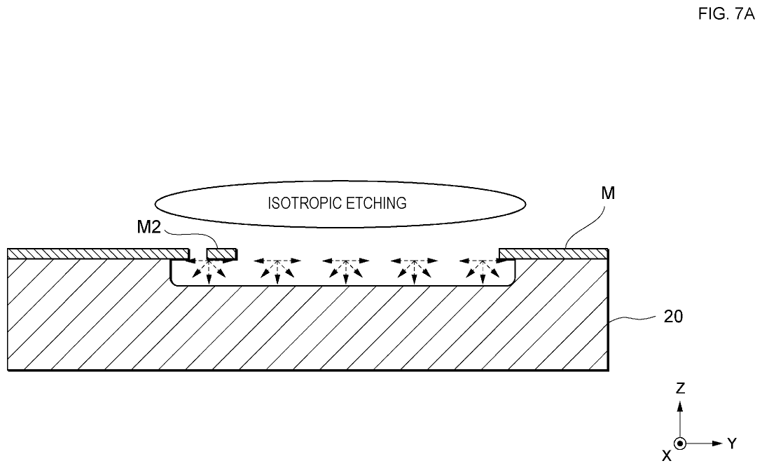

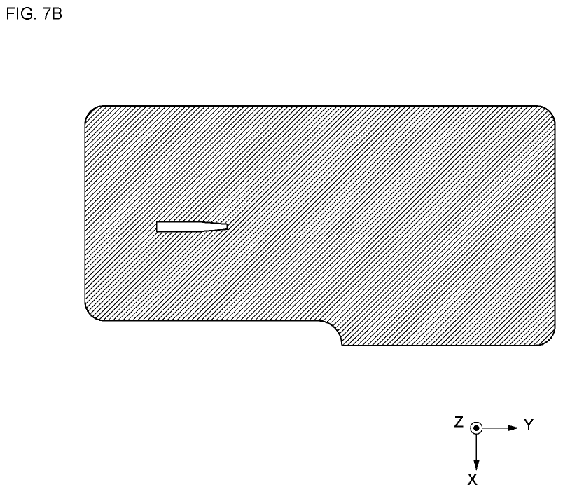

Next, as illustrated in FIG. 7A, while the upper surface of the lower lid 20 is covered with the mask M, the lower lid 20 is etched by isotropic etching. FIG. 7B illustrates an area of the lower lid 20 to be etched by isotropic etching in the step illustrated in FIG. 7A. Isotropic etching indicates a phenomenon in which a substance exposed to plasma performs etching in a radial direction. Therefore, as illustrated in FIG. 7B, the area of the lower lid 20 to be etched by isotropic etching in the step illustrated in FIG. 7A is an area of the lower lid 20 excluding a part of the pillar formation portion M3. That is, during isotropic etching, not only the area, of the area of the lower lid 20, not covered with the mask M, but also the area covered with the mask M are etched so as to be intruded from above. As a result, a relatively shallow recessed portion is formed on the upper surface of the lower lid 20. The step illustrated in FIG. 7A is an example of a first step.

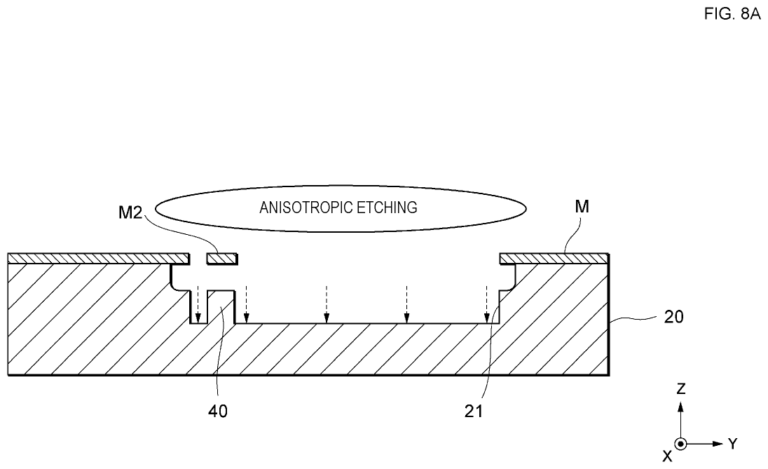

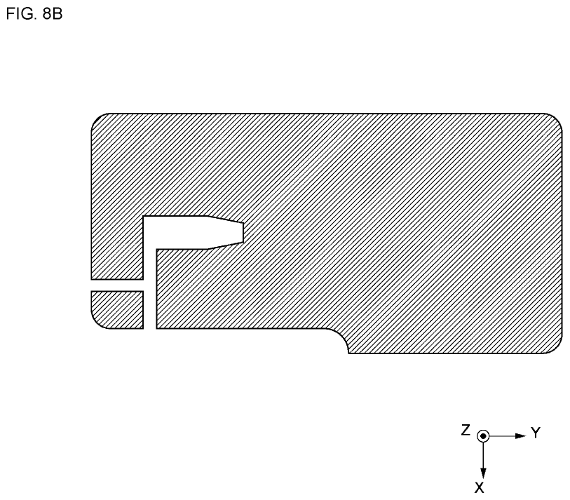

Next, as illustrated in FIG. 8A, while the upper surface of the lower lid 20 is covered with the mask M, the lower lid 20 is etched by anisotropic etching. FIG. 8B illustrates an area of the lower lid 20 to be etched by anisotropic etching in the step illustrated in FIG. 8A. Anisotropic etching indicates a phenomenon in which a substance exposed to plasma performs etching only in a specified direction. Therefore, as illustrated in FIG. 8B, the area of the lower lid 20 to be etched by anisotropic etching in the step illustrated in FIG. 8A is an area of the lower lid 20 excluding the pillar formation portion M3, the stopper formation portion M2, and the connection formation portion M4. That is, during anisotropic etching, only the area not covered with the mask M is etched, and the area covered with the mask M is not etched. As a result, on the upper surface of the lower lid 20, of the bottom surface of the relatively shallow recessed portion formed on the upper surface of the lower lid 20 in the step illustrated in FIG. 7A, etching is performed linearly from above on the area of the lower lid 20 excluding the pillar formation portion M3, the stopper formation portion M2, and the connection formation portion M4, and the pillar portion 42, the stopper portion 40, and the connection portion 41 are formed on the bottom surface of the recessed portion of the lower lid 20. The step illustrated in FIG. 8A is an example of a second step.

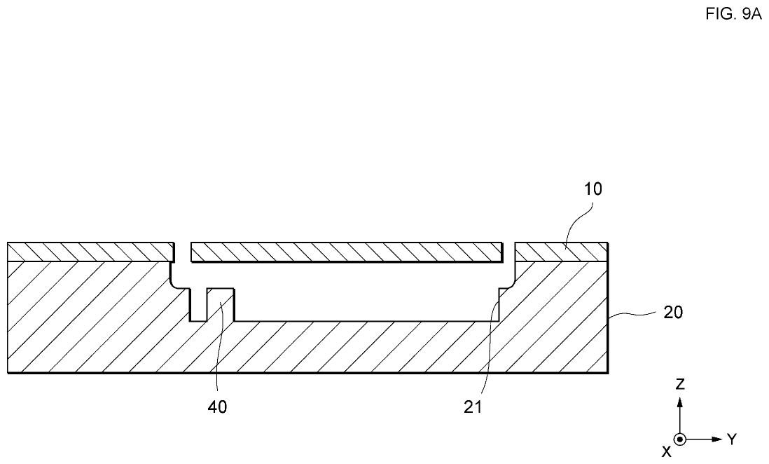

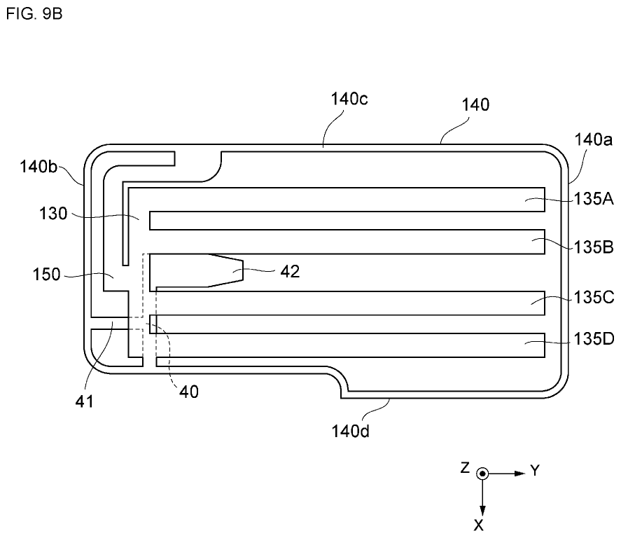

Next, as illustrated in FIG. 9A, after removing the mask M from the upper surface of the lower lid 20, the resonator 10 is stacked on the upper surface of the lower lid 20. As a result, as illustrated in FIG. 9B, in the resonance device 1, in a plan view of the lower lid 20, the stopper portion 40 is disposed below the base end portion of each of the vibration arm 135C and the vibration arm 135D, and the stopper portion 40 restricts collision of each of the vibration arm 135C and the vibration arm 135D with the bottom surface of the recessed portion 21 of the lower lid 20.

Next, the operation of the resonance device 1 according to the first exemplary embodiment will be described.

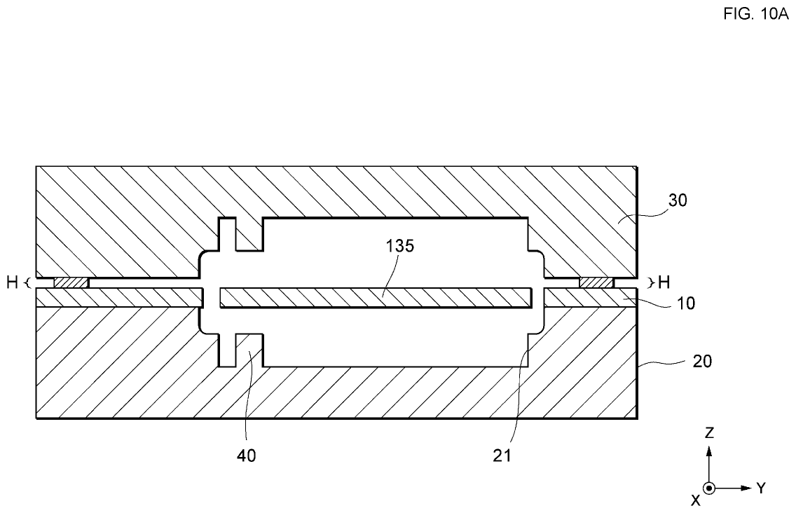

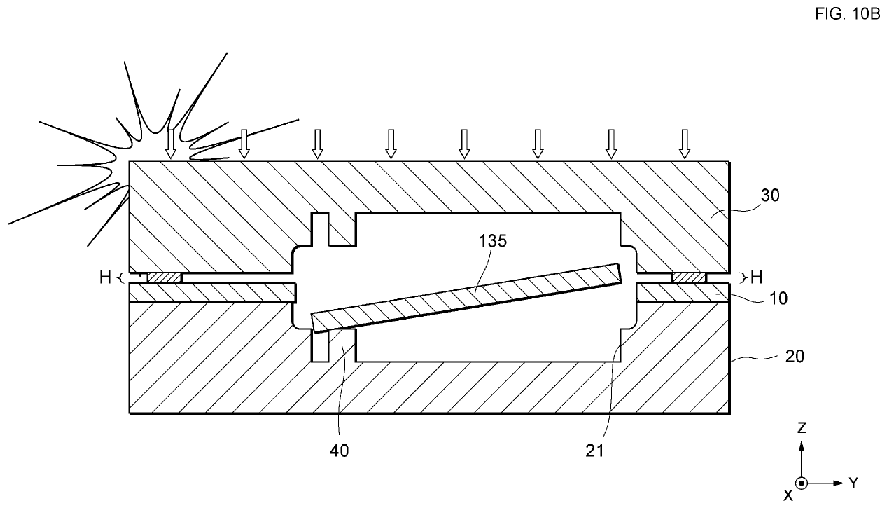

As illustrated in FIG. 10A, in the resonance device 1, when vibration of the resonator 10 is stopped, the longitudinal direction of the vibration arms 135 coincides with a horizontal direction, and a gap is interposed between the stopper portion 40 formed at the bottom surface of the recessed portion 21 of the lower lid 20 and the vibration arms 135.

Here, as illustrated in FIG. 10B, in the resonance device 1, when an external force is added to the upper lid 30 (e.g., in the upper left corner), the impact is transmitted from the upper lid 30 to the resonator 10. In this case, although not illustrated, in the resonator 10, the holding arm 150 is inclined with respect to the horizontal direction. In particular, in the present embodiment, the holding arm 150 locally holds the holding portion 140 and the base portion 130, the resonator 10 is likely to be inclined with respect to the horizontal direction, with a connection portion of the holding arm 150 and the base portion 130 as a fulcrum. In addition, as illustrated in FIG. 10B, the vibration arms 135 are inclined with respect to the horizontal direction. In this regard, in the present embodiment, since the base end portions of the vibration arms 135 come into contact with the stopper portion 40 formed at the bottom surface of the recessed portion 21, collision with the bottom surface of the recessed portion 21 is restricted. As a result, damage due to large displacement of the vibration arms 135 is suppressed.

By the way, in particular, in a case where the recessed portion 21 of the lower lid 20 is relatively deep, when applying a resist at a position where the stopper portion 40 is to be formed on the bottom surface of the recessed portion 21 after the recessed portion 21 is formed on the upper surface of the lower lid 20, an application failure of the resist, such as a liquid pool and defective coating, may occur due to a step between the upper surface of the lower lid 20 and the bottom surface of the recessed portion 21.

In this regard, in the present embodiment, after a resist provided with a predetermined pattern is applied to the upper surface of the lower lid 20, two types of etching (i.e., isotropic etching and anisotropic etching) having different characteristics are used in stages to form the stopper portion 40. Therefore, even when the recessed portion 21 of the lower lid 20 is relatively deep, the stopper portion 40 is suitably formed on the bottom surface of the recessed portion 21.

In the method for manufacturing the resonance device 1 according to the first exemplary embodiment, the step of forming the recessed portion 21 or 31 that forms the vibration space for the resonator 10 in the object that is at least one of the upper lid 30 and the lower lid 20 includes the first step of performing etching on the object by isotropic etching while the object is covered with the mask M having the peripheral portion M1 having a frame shape and the stopper formation portion M2 extending from the peripheral portion M1 toward the inside of the peripheral portion M1. Moreover, the second step of performing etching on the object subjected to etching by isotropic etching in the first step includes anisotropic etching while the object is covered with the mask M to form the stopper portion 40 at a position overlapping with the stopper formation portion M2 on the bottom surface of the recessed portion 21 or 31 in a plan view of the object. In this aspect, the stopper portion 40 is configured to restrict collision of the resonator 10 with the bottom surface of the recessed portion 21 or 31. Therefore, in the resonance device 1, on the bottom surface of the recessed portion 21 or 31 as the object, the stopper portion 40 extending from the inner side surface of the recessed portion 21 or 31 and being configured to restrict collision of the resonator 10 with the bottom surface of the recessed portion 21 or 31 is formed. As a result, for example, even when an external force is added to the resonance device 1, since the base end portions of the vibration arms 135 come into contact with the stopper portion 40 formed on the bottom surface of the recessed portion 21 or 31, collision with the bottom surface of the recessed portion 21 or 31 is restricted. As a result, damage due to large displacement of the vibration arms 135 is also suppressed.

In addition, in the method for manufacturing the resonance device 1 according to the first exemplary embodiment, since two types of etching having different characteristics are used in stages to form the stopper portion 40 on the bottom surface of the recessed portion 21 or 31 while the object is covered with the mask M, even when the recessed portion 21 or 31 is relatively deep, the stopper portion 40 is suitably formed on the bottom surface of the recessed portion 21 or 31.

In addition, in the method for manufacturing the resonance device 1 according to the first exemplary embodiment, since the stopper formation portion M2 is connected to the peripheral portion M1 in the mask M, peeling, floating, and reattachment of the stopper formation portion M2 is less likely to occur during etching. Therefore, occurrence of an etching failure and contamination of the inside of the resonance device 1 with pieces of the peeled stopper formation portion M2 can be suppressed.

### Second Exemplary Embodiment

In a second exemplary embodiment and the subsequent embodiments, matters common to the first embodiment will not be described, and only points different from the first embodiment will be described. In particular, descriptions regarding similar functions and advantageous effects provided by similar elements will not be described in every embodiment.

Processing for forming a stopper portion 40α on the lower lid 20 of the resonance device 1 according to the second embodiment will be described. Note that generally similar processing is performed when a stopper portion is formed on the upper lid 30 of the resonance device 1.

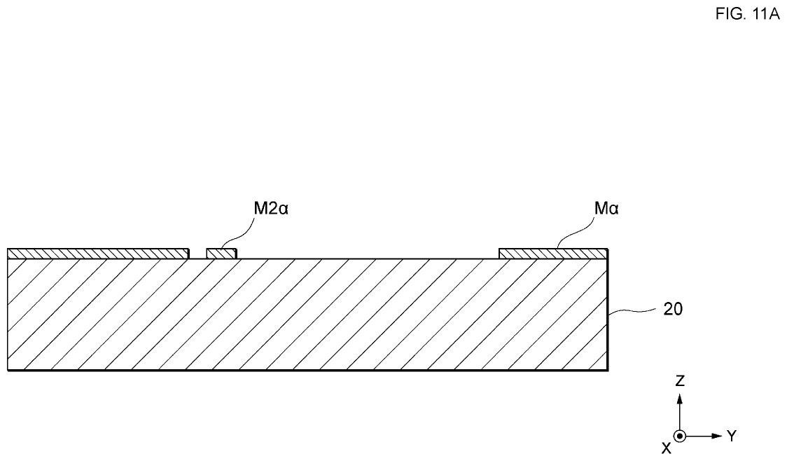

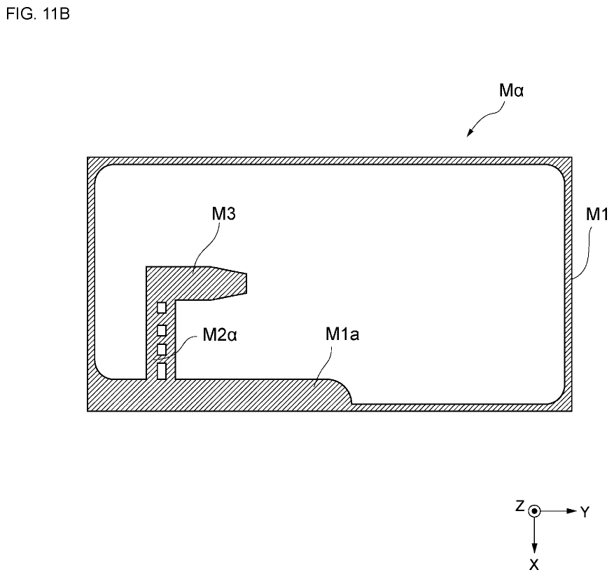

First, as illustrated in FIG. 11A, a resist is applied to the lower lid 20 so as to cover the lower lid 20 with the mask Mα. FIG. 11B illustrates a shape of the mask Mα in a plan view in a step illustrated in FIG. 11A. As illustrated in FIG. 11B, a stopper formation portion M2α of the mask Mα has a mesh shape. In addition, in the mask Mα, the connection formation portion M4 is omitted.

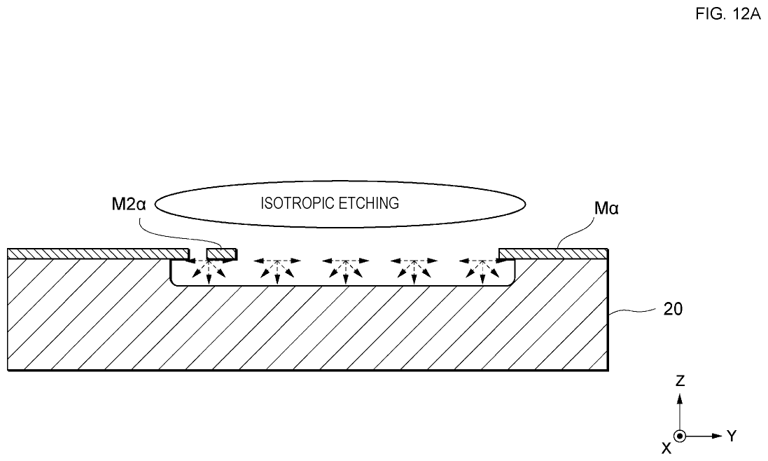

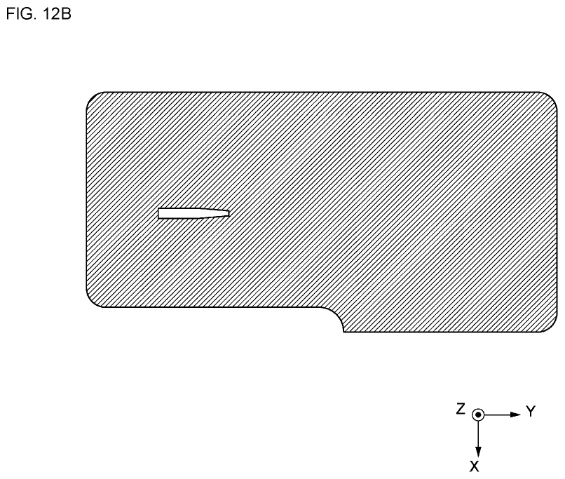

Next, as illustrated in FIG. 12A, while the lower lid 20 is covered with the mask Mα, the lower lid 20 is etched by isotropic etching. FIG. 12B illustrates an area of the lower lid 20 to be etched by isotropic etching in the step illustrated in FIG. 12A. As illustrated in FIG. 12B, the area of the lower lid 20 to be etched by isotropic etching in the step illustrated in FIG. 12A is an area of the lower lid 20 excluding a part of the pillar formation portion M3. The step illustrated in FIG. 12A is an example of the first step.

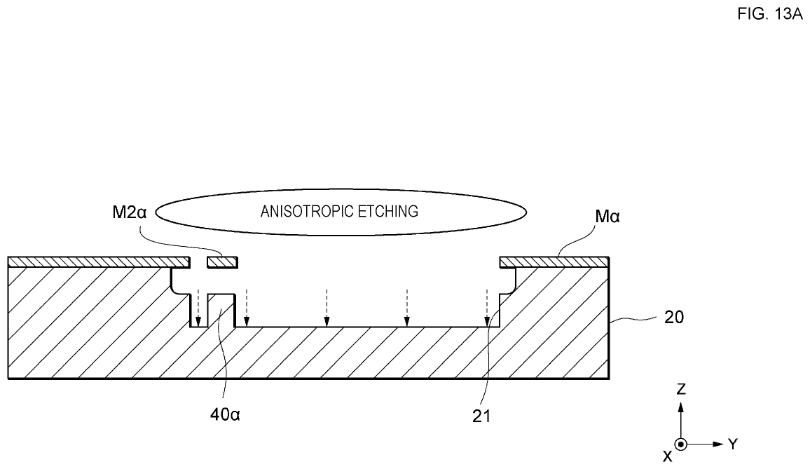

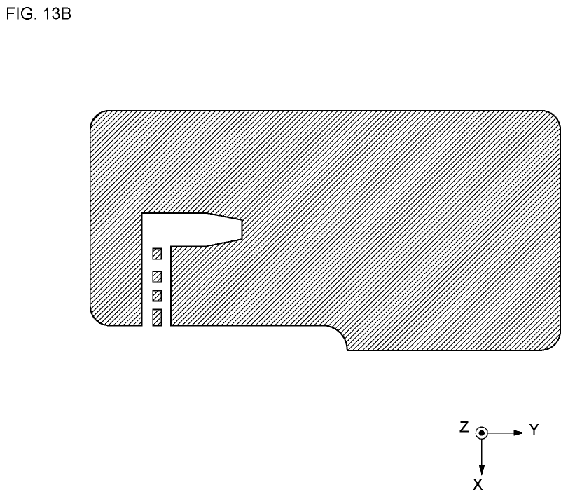

Next, as illustrated in FIG. 13A, while the lower lid 20 is covered with the mask Mα, the lower lid 20 is etched by anisotropic etching. FIG. 13B illustrates an area of the lower lid 20 to be etched by anisotropic etching in the step illustrated in FIG. 13A. As illustrated in FIG. 13B, the area of the lower lid 20 to be etched by anisotropic etching in the step illustrated in FIG. 13A is an area of the lower lid 20 excluding the pillar formation portion M3 and the stopper portion formation portion M2a. As a result, on the upper surface of the lower lid 20, of the relatively shallow recessed portion formed on the upper surface of the lower lid 20 in the step illustrated in FIG. 12A, etching is performed linearly from above on the area of the lower lid 20 excluding the pillar formation portion M3 and the stopper formation portion M2a, and the pillar portion 42 and a stopper portion 40α are formed on the bottom surface of the recessed portion of the lower lid 20. The step illustrated in FIG. 13A is an example of the second step.

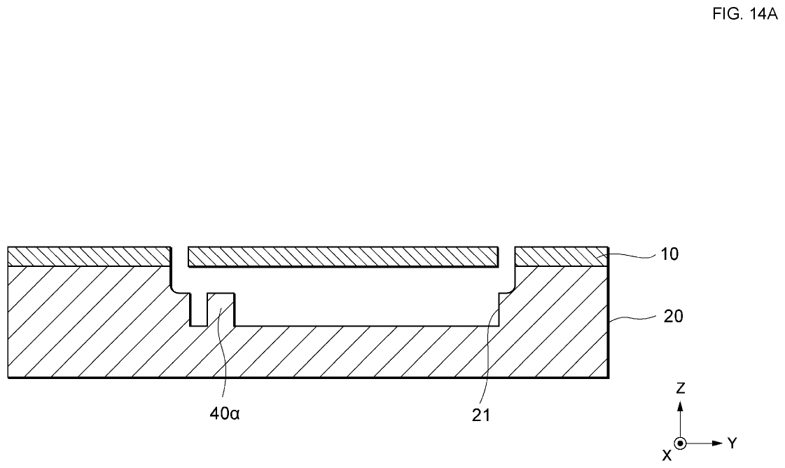

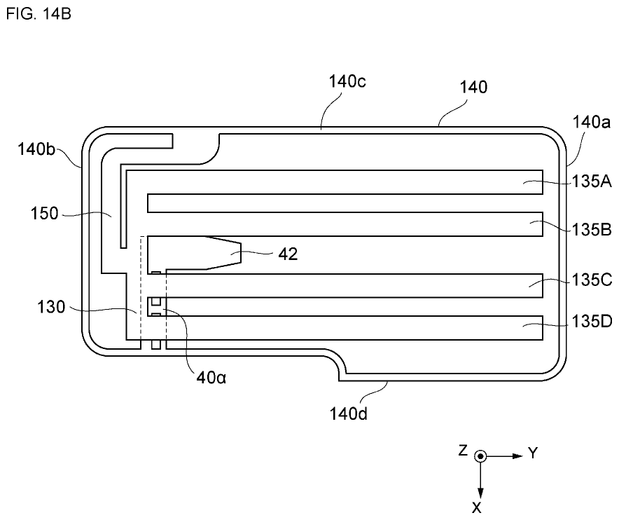

Next, as illustrated in FIG. 14A, after removing the mask Mα from the upper surface of the lower lid 20, the resonator 10 is stacked on the upper surface of the lower lid 20. As a result, as illustrated in FIG. 14B, in the resonance device 1, in a plan view of the lower lid 20, the stopper portion 40α is disposed below the base end portion of each of the vibration arm 135C and the vibration arm 135D, and the stopper portion 40α restricts collision of each of the vibration arm 135C and the vibration arm 135D with the bottom surface of the recessed portion 21 of the lower lid 20.

In the method for manufacturing the resonance device 1 according to the second embodiment, the stopper formation portion M2α of the mask Mα has a mesh shape. Therefore, since the rigidity of the stopper portion 40α formed on the bottom surface of the recessed portion 21 of the lower lid 20 can be improved, even when a gap is formed between the mask Mα and the upper surface of the lower lid 20 by isotropic etching, breakage of the mask Mα can be suppressed.

### Third Exemplary Embodiment

Processing for forming a stopper portion on the lower lid 20 of the resonance device 1 according to a third exemplary embodiment will be described. It is noted that generally similar processing is performed when a stopper portion is formed on the upper lid 30 of the resonance device 1.

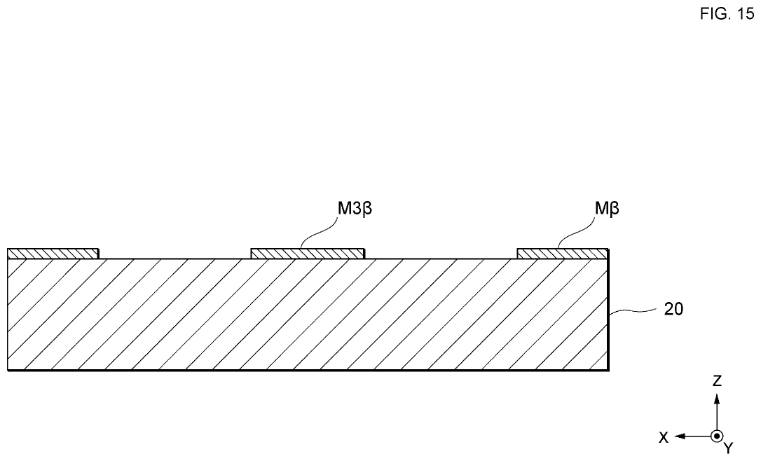

First, as illustrated in FIG. 15, a resist is applied to the upper surface of the lower lid 20 so as to cover the upper surface of the lower lid 20 with a mask Mβ. In the present embodiment, a plurality of areas including the central position in the Y-axis direction in the lower lid 20 and both end positions in the Y-axis direction in the lower lid 20 is covered with the mask Mβ.

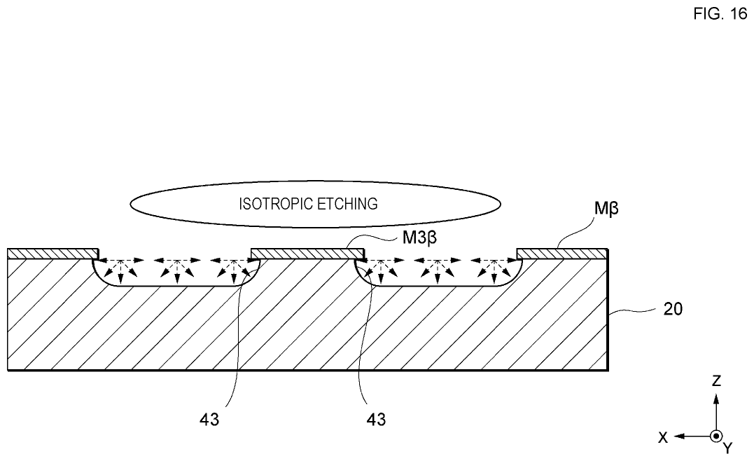

Next, as illustrated in FIG. 16, while the upper surface of the lower lid 20 is covered with the mask Mβ, the lower lid 20 is etched by isotropic etching. In this case, the area of the lower lid 20 to be etched by isotropic etching in the step illustrated in FIG. 16 is an area not covered with the mask Mβ. In addition, during isotropic etching, not only the area, of the area of the lower lid 20, not covered with the mask Mβ, but also the area covered with the mask Mβ are etched so as to be intruded from above. As a result, a relatively shallow recessed portion that is open wide on the upper side is formed on the upper surface of the lower lid 20. The recessed portion functions as a taper portion 43 described later. The step illustrated in FIG. 16 is an example of the first step.

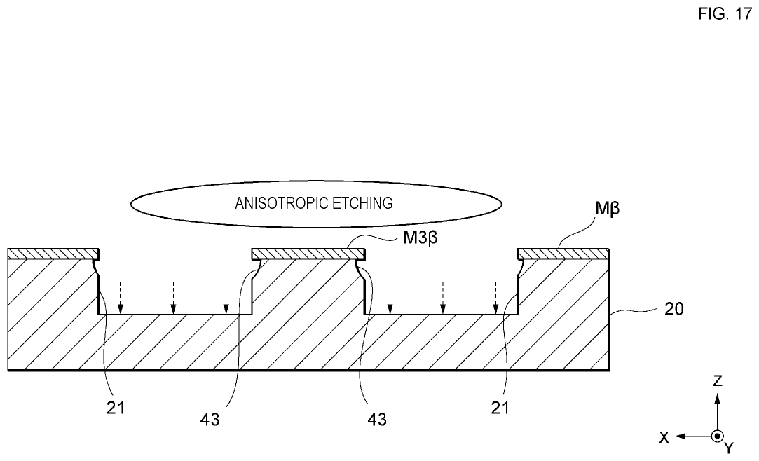

Next, as illustrated in FIG. 17, while the lower lid 20 is covered with the mask Mβ, the lower lid 20 is etched by anisotropic etching. The area of the lower lid 20 to be etched by anisotropic etching in the step illustrated in FIG. 17 is an area of the lower lid 20 excluding the area covered with the mask Mβ. As a result, on the upper surface of the lower lid 20, of the relatively shallow recessed portion formed on the upper surface of the lower lid 20 in the step illustrated in FIG. 16, etching is performed linearly from above on the area of the lower lid 20 not covered with the mask Mβ. In addition, in a plan view of the lower lid 20, at a position overlapping with a pillar formation portion M3β on the bottom surface of the recessed portion 21, a pillar portion 42β having the taper portion 43 that restricts collision of the resonator 10 with the bottom surface of the recessed portion 21 is formed. The taper portion 43 gradually increases in width toward the bottom surface of the recessed portion 21 and functions as a stopper portion. The step illustrated in FIG. 17 is an example of the second step.

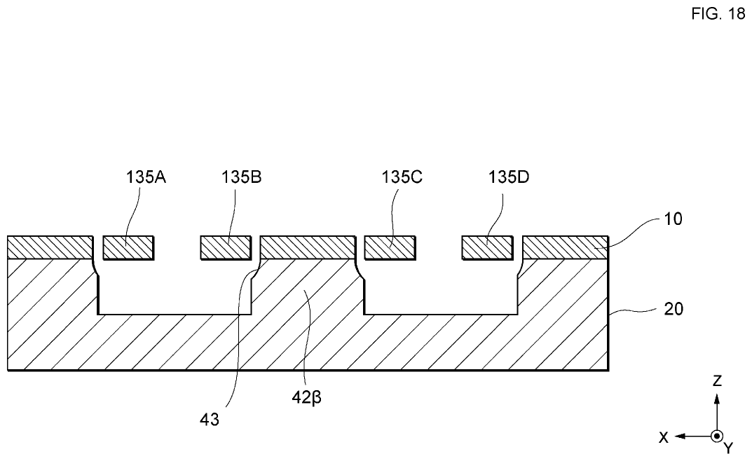

Next, as illustrated in FIG. 18, after removing the mask Mβ from the upper surface of the lower lid 20, the resonator 10 is stacked on the upper surface of the lower lid 20. As a result, in the resonance device 1, in a plan view of the lower lid 20, the taper portion 43 of the pillar portion 42β is disposed below the base end portion of each of the vibration arm 135B and the vibration arm 135C, and collision of each of the vibration arm 135B and the vibration arm 135C with the bottom surface of the recessed portion 21 of the lower lid 20 is restricted by the taper portion 43.

Next, the operation of the resonance device 1 according to the third exemplary embodiment will be described.

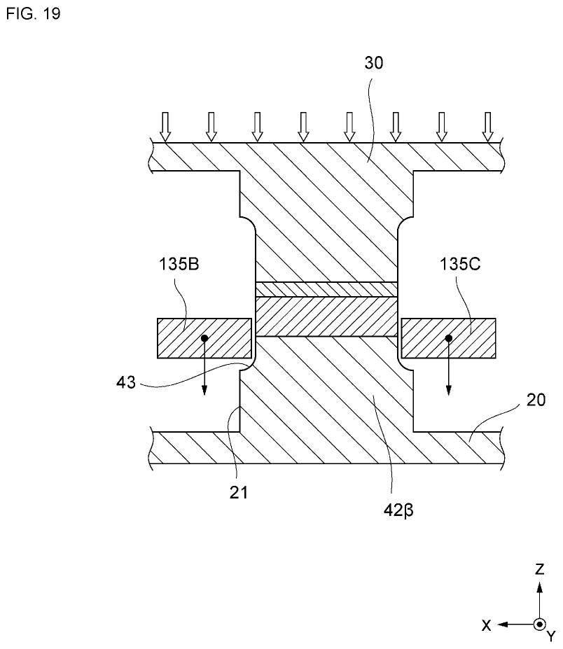

As illustrated in FIG. 19, in the resonance device 1, when an external force is added to the upper lid 30, the impact is transmitted from the upper lid 30 to the resonator 10. Although not illustrated, in the resonator 10, the vibration arms 135 are inclined with respect to the horizontal direction and moves downward. In particular, in the present embodiment, since the holding arm 150 locally holds the holding portion 140 and the base portion 130, the vibration arms 135 are likely to be inclined with respect to the horizontal direction, with a connection portion of the holding arm 150 and the base portion 130 as a fulcrum. In this regard, as illustrated in FIG. 19, in the present embodiment, since the base end portion of each of the vibration arm 135B and the vibration arm 135C comes into contact with the taper portion 43 formed in the pillar portion 42β, collision with the bottom surface of the recessed portion 21 is restricted. As a result, damage due to large displacement of the vibration arm 135B and the vibration arm 135C is suppressed.

In the method for manufacturing the resonance device 1 according to the third exemplary embodiment, the step of forming the recessed portion 21 or 31 that forms the vibration space for the resonator 10 in the object that is at least one of the upper lid 30 and the lower lid 20 includes the first step of performing etching on the object covered with the mask Mβ having the pillar formation portion M3β by isotropic etching, and the second step of performing etching on the object subjected to etching by isotropic etching in the first step by anisotropic etching while the object is covered with the mask Mβ to form the pillar portion 42β at a position overlapping with the pillar formation portion M3β on the bottom surface of the recessed portion 21 or 31 in a plan view of the object, the pillar portion 42β having the taper portion 43 that gradually increases in width toward the bottom surface of the recessed portion 21 or 31 and is configured to restrict collision of the resonator 10 with the bottom surface of the recessed portion 21 or 31. Therefore, in the resonance device 1, even when an external force is added to the upper lid 30, and the vibration arms 135 are inclined with respect to the horizontal direction and moves downward, since the base end portions of the vibration arms 135 come into contact with the taper portion 43 formed in the pillar portion 42, collision with the bottom surface of the recessed portion 21 or 31 is restricted. As a result, damage due to large displacement of the vibration arms 135 is suppressed.

In addition, in the method for manufacturing the resonance device 1 according to the third exemplary embodiment, since the mask Mβ does not have to be formed into a bridge shape, compared to a case in which the mask Mβ is formed into a bridge shape, breakage of the mask Mβ can be suppressed.

It is noted that each of the above embodiments may be implemented in the following modes.

In each of the above embodiments, a case in which a resist is applied to the object that is at least one of the upper lid 30 and the lower lid 20 to form the masks M, Mα, and Mβ has been exemplified, but the method of forming the masks M, Mα, and Mβ is not limited thereto, and, for example, a metal mask provided with a predetermined pattern may be used in alternative aspects.

In the first and second embodiments, the stopper portions 40 and 40α may be provided without providing the pillar portion 42 on the bottom surface of the recessed portion 21 or 31 of the object that is at least one of the upper lid 30 and the lower lid 20.

In the above first embodiment, the connection portion 41 that connects the side wall 23 or 33 of the object that is at least one of the upper lid 30 and the lower lid 20 to the stopper portion 40 may be omitted.

In the above first and second embodiments, the stopper portions 40 and 40α do not have to extend from the side wall 23 or 33 of the object that is at least one of the upper lid 30 and the lower lid 20 to the substantially central position in the X-axis direction in the recessed portion 21 or 31, and in a plan view of the object, the stopper portions 40 and 40α may cross the base end portions of at least some of the vibration arms 135 in a direction intersecting with the longitudinal direction of the vibration arms 135.

In the above first and second embodiments, the stopper portions 40 and 40α do not have to be disposed at a position overlapping with the base end portions of the vibration arms 135 in a plan view of the object that is at least one of the upper lid 30 and the lower lid 20 and, for example, may be disposed at a position overlapping with middle portions or leading end portions of the vibration arms 135 in a plan view of the object.

Hereinafter, supplementary notes for some or all of the exemplary embodiments will be given, and effects thereof will be described. Note that the exemplary embodiments of present invention is not limited to the following supplementary notes.

According to an exemplary aspect of the present invention, a method is provided for manufacturing a resonance device having a resonator and an upper lid and a lower lid provided to face each other with the resonator interposed between the upper lid and the lower lid. The exemplary method includes forming a recessed portion that forms a vibration space for the resonator in an object that is at least one of the upper lid and the lower lid, in which the forming of the recessed portion in the object includes performing etching on the object by isotropic etching while the object is covered with a mask having a peripheral portion having a frame shape and a stopper formation portion extending from the peripheral portion toward an inside of the peripheral portion. The method further includes performing etching on the object subjected to etching by isotropic etching in the first step by anisotropic etching while the object is covered with the mask to form a stopper portion at a position overlapping with the stopper formation portion on a bottom surface of the recessed portion in a plan view of the object. In this aspect, the stopper portion is configured to restrict collision of the resonator with the bottom surface of the recessed portion.

In an aspect of the exemplary method, the mask further has a pillar formation portion that is connected to the stopper formation portion and has a larger area than the stopper formation portion in a plan view of the object.

In an aspect of the exemplary method, the stopper formation portion extends in one direction from the peripheral portion of the mask, and in a plan view of the object, a dimension of the pillar formation portion in a width direction intersecting with the longitudinal direction of the stopper formation portion is larger than a dimension of the stopper formation portion in a same direction.

In an aspect of the exemplary method, the stopper formation portion has a mesh shape.

According to an exemplary aspect of the present invention, a method is provided for manufacturing a resonance device having a resonator and an upper lid and a lower lid provided to face each other with the resonator interposed between the upper lid and the lower lid. In this aspect, the method includes forming a recessed portion that forms a vibration space for the resonator in an object that is at least one of the upper lid and the lower lid, in which the forming of the recessed portion in the object includes performing etching on the object by isotropic etching while the object is covered with a mask having a pillar formation portion. The method further includes performing etching on the object subjected to etching by isotropic etching in the first step by anisotropic etching while the object is covered with the mask to form a pillar portion at a position overlapping with the pillar formation portion on a bottom surface of the recessed portion in a plan view of the object. In this aspect, the pillar portion has a taper portion that gradually increases in width toward the bottom surface of the recessed portion and is configured to restrict collision of the resonator with the bottom surface of the recessed portion.

According to an exemplary aspect of the present invention, a resonance device is provided that includes a resonator, and an upper lid and a lower lid provided to face each other with the resonator interposed between the upper lid and the lower lid. Moreover, at least one of the upper lid and the lower lid has a recessed portion that forms a vibration space for the resonator. A bottom surface of the recessed portion is provided with a stopper portion that extends from an inner side surface of the recessed portion and is configured to restrict collision of the resonator with the bottom surface of the recessed portion.

In an exemplary aspect of is the resonance device, the bottom surface of the recessed portion is further provided with a pillar portion that is connected to the stopper portion and has a larger area than the stopper portion in a plan view of the upper lid and the lower lid.

According to an exemplary aspect of the present invention, a resonance device is provided that includes a resonator, and an upper lid and a lower lid provided to face each other with the resonator interposed between the upper lid and the lower lid. Moreover, at least one of the upper lid and the lower lid has a recessed portion that forms a vibration space for the resonator. A bottom surface of the recessed portion is provided with a pillar portion having a taper portion that gradually increases in width toward the bottom surface of the recessed portion and is configured to restrict collision of the resonator with the bottom surface of the recessed portion.

As described above, according to an exemplary aspect of the present invention, breakage of a resonator can be suppressed.

In general, it is noted that the exemplary embodiments described above are intended to facilitate an understanding of the present invention and are not intended to limit interpretation of the present invention. The exemplary embodiments of the present invention can be modified or improved without departing from the spirit of the invention, and equivalents to the present invention are also included in the present invention. That is, appropriate design changes made to the embodiments by one skilled in the art are included in the scope of the present invention as long as the changes have the features of the present invention. For example, the elements included the embodiments and the disposition, materials, conditions, shapes, sizes, and the like of the elements are not limited to those exemplified in the embodiments and can be appropriately changed. In addition, the embodiments are illustrative, and, of course, the configurations shown in different embodiments can be partially replaced or combined with each other, and such configurations are also included in the scope of the present invention as long as they include the features of the present invention.

### REFERENCE SIGNS LIST

10 resonator
20 upper lid
30 lower lid
40 stopper portion
40α stopper portion
41 connection portion
42 pillar portion
42β pillar portion
43 taper portion
120 vibration portion
130 base portion
135A to 135D vibration arm
140 holding portion
140a to 140d frame body
150 holding arm
M mask
Mα mask
Mβ mask
M1 peripheral portion
M2 stopper formation portion
M2α stopper formation portion
M3 pillar formation portion
M3β pillar formation portion
M4 connection formation portion

1. A method for manufacturing a resonance device comprising:
forming a recessed portion in an object for a vibration space for a resonator, the object configured as at least one of an upper lid and a lower lid that face each other with the resonator interposed therebetween, the recessed portion formed by etching the object by isotropic etching while the object is covered with a mask having a peripheral portion having a frame shape and a stopper formation portion that extends from the peripheral portion towards an inside of the peripheral portion; and
etching the object by anisotropic etching while the object is covered with the mask to form a stopper at a position overlapping with the stopper formation portion on a bottom surface of the recessed portion in a plan view of the object, such that the stopper is configured to restrict collision of the resonator with the bottom surface of the recessed portion.

2. The method for manufacturing a resonance device according to claim 1, further comprising providing the mask to have a pillar formation portion that is connected to the stopper formation portion.

3. The method for manufacturing of a resonance device according to claim 2, wherein the pillar formation portion has a larger area than the stopper formation portion in the plan view of the object.

4. The method for manufacturing a resonance device according to claim 3, wherein the stopper formation portion extends in one direction from the peripheral portion of the mask.

5. The method for manufacturing a resonance device according to claim 4, further comprising forming, in the plan view of the object, a dimension of the pillar formation portion in a width direction that intersects with a longitudinal direction of the stopper formation portion to be larger than a dimension of the stopper formation portion in a same direction.

6. The method for manufacturing a resonance device according to claim 1, further comprising forming the stopper formation portion to have a mesh shape.

7. The method for manufacturing a resonance device according to claim 1, further comprising providing the resonator to have a base and a plurality of vibration arms extending therefrom.

8. The method for manufacturing a resonance device according to claim 7, further comprising forming the stopper to cross base end portions of the plurality of vibration arms.

9. A method for manufacturing a resonance device comprising:
forming a recessed portion in an object for a vibration space for a resonator, the object configured as at least one of an upper lid and a lower lid that face each other with the resonator interposed therebetween, the recessed portion formed by etching the object by isotropic etching while the object is covered with a mask having a pillar formation portion; and
etching the object by anisotropic etching while the object is covered with the mask to form a pillar portion at a position overlapping with the pillar formation portion on a bottom surface of the recessed portion in a plan view of the object, such that the pillar portion has a taper portion that gradually increases in width towards the bottom surface of the recessed portion and is configured to restrict collision of the resonator with the bottom surface of the recessed portion.

10. A resonance device comprising:
a resonator;
an upper lid and a lower lid that face each other with the resonator interposed therebetween, at least one of the upper lid and the lower lid having a recessed portion that forms a vibration space to accommodate the resonator; and
a stopper disposed on a bottom surface of the recessed portion that extends from an inner side surface of the recessed portion and is configured to restrict collision of the resonator with the bottom surface of the recessed portion.

11. The resonance device according to claim 10, further comprising a pillar portion on the bottom surface of the recessed portion that is connected to the stopper.

12. The resonance device according to claim 11, wherein the pillar portion has a larger area than the stopper in a plan view of the upper lid and the lower lid.

13. The resonance device according to claim 11, wherein the pillar portion extends in a same direction as a plurality of vibration arms of the resonator.

14. The resonance device according to claim 10, wherein the resonator includes a base and a plurality of vibration arms extending therefrom.

15. The resonance device according to claim 14, wherein the stopper crosses base end portions of the plurality of vibration arms.

16. The resonance device according to claim 10, wherein a bottom plate of the lower lid includes a connection portion that connects the stopper to the inner side surface of the recessed portion.

17. A resonance device comprising:
a resonator; and
an upper lid and a lower lid that face each other with the resonator interposed therebetween, at least one of the upper lid and the lower lid having a recessed portion that forms a vibration space to accommodate the resonator; and
a pillar portion disposed on a bottom surface of the recessed portion and having a taper portion that gradually increases in width toward the bottom surface of the recessed portion and is configured to restrict collision of the resonator with the bottom surface of the recessed portion.

18. The resonance device according to claim 17, wherein the resonator includes a base and a plurality of vibration arms extending therefrom.

19. The resonance device according to claim 18, wherein the pillar portion extends in a same direction as the plurality of vibration arms of the resonator.

20. The resonance device according to claim 10, wherein a bottom plate of the lower lid includes a connection portion that connects the pillar portion to the inner side surface of the recessed portion.
